(19) United States
(12) Patent Application Publication
(10) Pub. No.: US 2005/0079716 A1
(43) Pub. Date: Apr. 14, 2005

(54) Semiconductor optical device and method for manufacturing the same

(75) Inventors: Shinji Yoshihara, Nagoya-city (JP); Junji Oohara, Nisshin-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/958,222

(22) Filed: Oct. 5, 2004

(30) Foreign Application Priority Data
Oct. 6, 2003 (JP) 2003-347147

(51) Int. Cl. H01L 21/302; H01L 21/461

(52) U.S. Cl. 438/689

(57) ABSTRACT

A method for manufacturing a semiconductor optical device is provided. The device includes first and second optical parts disposed on a semiconductor substrate and optically connected each other. The method includes the steps of: etching the substrate so that a first-optical-part-to-be-formed region of the substrate is formed to have the same outline as the first optical part and a positioning member for determining a position of the second optical part is formed in the substrate; forming the first optical part from the first-optical-part-to-be-formed region; and mounting the second optical part on the substrate in such a manner that the second optical part contacts the positioning member.

### CROSS REFERENCE TO RELATED APPLICATION

This application is based on Japanese Patent Application No. 2003-347147 filed on Oct. 6, 2003, the disclosure of which is incorporated herein by reference.

### FIELD OF THE INVENTION

The present invention relates to a semiconductor optical device and a method for manufacturing a semiconductor optical device.

### BACKGROUND OF THE INVENTION

A semiconductor optical device is disclosed, for example, in Unexamined Japanese Patent Application Publication No. H05-241047. The device includes a semiconductor laser, and a semiconductor substrate having a micro lens and a guide groove. The semiconductor laser is disposed in the guide groove for guiding a laser beam of the laser.

The device is manufactured as follows. Firstly, the semiconductor substrate is etched so that a portion for the micro lens and the guide groove is formed. Then, a SiO₂ film is formed on the portion by a sputtering method. Then, the SiO₂ film is etched so that the micro lens is formed. Further, the semiconductor substrate is etched so that the guide groove is formed. Then, the semiconductor laser is mounted in the guide groove of the substrate.

Since the laser is disposed in the guide groove so that a distance between the laser and the micro lens is easily controlled. Accordingly, in the semiconductor optical device, a positioning of the micro lens and the laser is easily controlled so that optical connection coefficient between the micro lens and the laser is improved.

However, in the above method for manufacturing the device, the micro lens and the guide groove are formed individually. Therefore, the relative positioning of the micro lens and the laser is deviated by a manufacturing error and the like. For example, when a mask for forming the micro lens in the etching process is deviated, the positioning of the micro lens is also deviated. Further, positioning of other optical parts such as the laser may be also deviated.

### SUMMARY OF THE INVENTION

In view of the above-described problem, it is an object of the present invention to provide a semiconductor optical device having high accuracy of positioning of optical parts. It is another object of the present invention to provide a method for manufacturing a semiconductor optical device having high accuracy of positioning of optical parts.

A method for manufacturing a semiconductor optical device is provided. The device includes first and second optical parts disposed on a semiconductor substrate and optically connected each other. The method includes the steps of: etching the substrate so that a first-optical-part-to-be-formed region of the substrate is formed to have the same outline as the first optical part and a positioning member for determining a position of the second optical part is formed in the substrate; forming the first optical part from the first-optical-part-to-be-formed region; and mounting the second optical part on the substrate in such a manner that the second optical part contacts the positioning member.

The method provides the device having high accuracy of positioning of optical parts. Specifically, the positioning relationship between the first optical part and the positioning member is determined only by the accuracy of etching. Therefore, the accuracy of the positioning relationship in this device becomes higher. Further, the accuracy of the positioning relationship between the first and second optical parts also becomes higher. Therefore, the optical coupling coefficient between the first and second optical parts is improved.

Further, a semiconductor optical device includes: a semiconductor substrate; a base integrated with the substrate; a first optical part disposed on the first base and integrated with the substrate; a second optical part; and a positioning member for determining a position of the second optical part. The positioning member is integrated with the substrate. The second optical part contacts the positioning member so that the first and second optical parts are connected optically.

The above device has high accuracy of positioning of optical parts. Specifically, the positioning relationship between the first optical part and the positioning member is determined only by the manufacturing accuracy of the first optical part and the positioning member. Therefore, the accuracy of the positioning relationship in this device becomes higher. Further, the accuracy of the positioning relationship between the first and second optical parts also becomes higher. Therefore, the optical coupling coefficient between the first and second optical parts is improved.

In the above device, the shape of the base is the same as the first optical part. Therefore, a stress generated at an interface between the first optical part and the base is reduced. Therefore, the strength of the first optical part is improved so that reliability of the first optical part is increased. Further, in the device, the stress generated at the interface between the first optical part and the base 1b by the difference of the thermal expansion coefficient is reduced by a deformation of the base. Thus, the reliability of the first optical part is increased.

### BRIEF DESCRIPTION OF THE DRAWINGS

The above and other objects, features and advantages of the present invention will become more apparent from the following detailed description made with reference to the accompanying drawings. In the drawings:

FIG. 1 is a perspective view showing a semiconductor optical device according to a first embodiment of the present invention;

FIG. 2 is a cross sectional view showing the device taken along line II-II in FIG. 1;

FIG. 3 is a perspective view showing a part of the device shown as III in FIGS. 1 and 2;

FIGS. 4A-4C are views explaining a method for manufacturing the device according to the first embodiment;

FIGS. 5A-5C are views explaining the method for manufacturing the device according to the first embodiment;

FIGS. 6A-6C are views explaining the method for manufacturing the device according to the first embodiment;

FIG. 7 is a view explaining the method for manufacturing the device according to the first embodiment;

FIGS. 8A and 8B are views explaining the method for manufacturing the device according to the first embodiment;

FIG. 9A is a plan view explaining the method for manufacturing the device according to the first embodiment, FIG. 9B is a cross sectional view showing the device taken along line IXB-IXB in FIG. 9A, and FIG. 9C is a cross sectional view showing the device taken along line IXC-IXC in FIG. 9A;

FIG. 10A is a plan view explaining the method for manufacturing the device according to the first embodiment, FIG. 10B is a cross sectional view showing the device taken along line XB-XB in FIG. 10A, and FIG. 10C is a cross sectional view showing the device taken along line XC-XC in FIG. 10A;

FIG. 11 is a partial plan view explaining the method for manufacturing the device according to the first embodiment;

FIG. 12 is a cross sectional view showing a semiconductor optical device according to a second embodiment of the present invention;

FIG. 13 is a cross sectional view showing a semiconductor optical device according to a third embodiment of the present invention;

FIG. 14 is a partial plan view explaining a method for manufacturing the device according to the third embodiment;

FIG. 15A is a cross sectional view showing the device taken along line XVA-XVA in FIG. 14, and FIG. 15B is a cross sectional view showing the device taken along line XVB-XVB in FIG. 14;

FIGS. 16A-16D are cross sectional views explaining a method for manufacturing a semiconductor optical device according to a fourth embodiment of the present invention;

FIG. 17 is a cross sectional view showing a semiconductor optical device according to the fourth embodiment; and

FIG. 18 is a cross sectional view showing another semiconductor optical device according to the fourth embodiment.

### DETAILED DESCRIPTION OF THE PREFERRED EMBODIMENTS

### First Embodiment

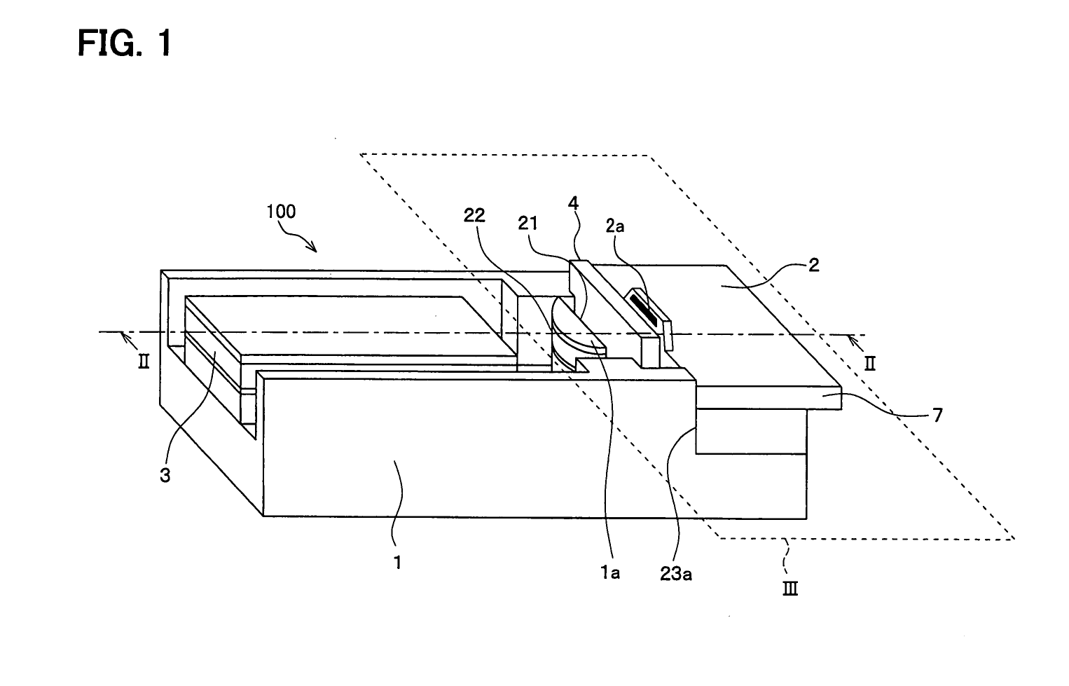

A semiconductor optical device 100 according to a first embodiment of the present invention is shown in FIGS. 1-3. Here, a heat sink 6 and related parts are not shown in FIG. 1. The device 100 includes the first micro lens 1a as the first optical part, a micro lens board 4 as the second micro lens, a laser diode board 2 as the second optical part, an optical waveguide 3 as the third optical part, and a heat sink 6, which are formed on a semiconductor substrate 1. The micro lens board 4 is mounted on the substrate 1 independently so that the micro lens board 4 is independent from the micro lens 1a.

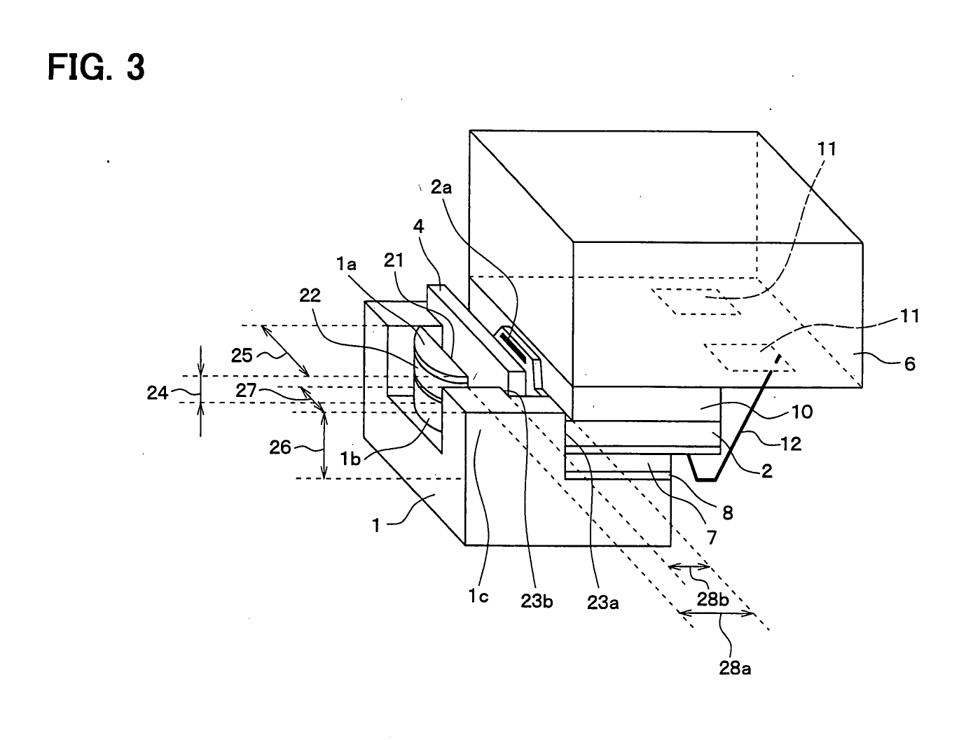

The first micro lens 1a is a plane convex type cylindrical lens. As shown in FIG. 3, the lens 1a includes an entrance surface 21 and an exit surface 22. The entrance surface 21 is a flat surface, and the exit surface 22 is a convex surface. The laser beam outputted from the laser diode board 2 is inputted into the entrance surface 21 of the first micro lens 1a. Then, the laser beam is outputted from the exit surface 22 of the first micro lens 1a. The first micro lens 1a is disposed on a micro lens base 1b, which is integrally formed with the semiconductor substrate 1. Here, the micro lens base 1b and the semiconductor substrate 1 are formed from the same material. This is, the micro lens base 1b and the substrate 1 are not different independent parts to bond each other for mounting the micro lens base 1b on the substrate 1. Thus, the micro lens base 1b and the substrate 1 are continuously connected. Further, the micro lens base 1b has the same cross-sectional shape as the micro lens 1a. Specifically, the outline of the micro lens base 1b is the same as the micro lens 1a.

The micro lens board 4 is independently mounted on the substrate 1. The micro lens board 4 includes a plane convex type cylindrical lens. The micro lens board 4 is disposed between the first micro lens 1a and the laser diode board 2. A laser diode of the laser diode board 2 irradiates a laser beam. The laser beam expands as the laser beam advances. The expanded laser beam is collimated by the micro lens board 4 in a fast direction. Then, the collimated laser beam collimated in the fast axis is inputted into the first micro lens 1a. Further, the inputted laser beam inputted into the first micro lens 1a is collimated by the first micro lens 1a in a slow axis. Then, the collimated laser beam collimated in the slow axis is outputted from the first micro lens 1a. The semiconductor device 100 can be used for measurement equipment for measuring a distance between the device 100 and an object in such a manner that the collimated laser beam enters into a polygon mirror and the like to scan the laser beam.

The substrate 1 is made of, for example, silicon. The first micro lens 1a is made of silicon oxide. The first micro lens 1a has a thickness 24 in a vertical direction and a width 25 in a horizontal direction. The thickness 24 as a height of the first micro lens 1a is equal to or larger than 10 μm . In FIG. 1, the thickness 24 is about 100 μm . The width 25 is about 500 μm .

On the substrate 1, the first micro lens 1a and a positioning member 1c are disposed. The positioning member 1c is disposed on one surface of the substrate 1, which is disposed on the first micro lens 1a side. The positioning member 1c and the substrate 1 are integrated, similar to the micro lens base 1b. The positioning member 1c is disposed outside from the first micro lens 1a on the substrate 1.

As shown in FIG. 3, the positioning member 1c is disposed on both sides of the first micro lens 1a. The positioning member 1c includes the first and second reference surfaces 23a, 23b for positioning the first micro lens 1a, the laser diode board 2, and the micro lens board 4. The first and second reference surfaces 23a, 23b are parallel to the entrance surface 21 of the first micro lens 1a. The laser diode board 2 contacts the first reference surface 23a. The micro lens board 4 contacts the second reference surface 23b.

The laser diode board 2 includes an emission surface 2a, which faces the entrance surface 21 of the first micro lens 1a through the micro lens board 4. The laser beam is outputted from thee mission surface 2a of the laser diode board 2. The laser diode of the laser diode board 2 optically connects to the first micro lens 1a. Specifically, the laser diode board 2 is disposed on the substrate 1 through a sub-mounting member 7 on the first micro lens side. A part of a side surface of the laser diode board 2 contacts the side of the positioning member 1c. The side surface of the laser diode board 2 is the emission surface 2a, and a part of the side surface of the laser diode board 2 contacts the first reference surface 23a.

The thickness 26 (i.e., the height) of the positioning member 1c in the vertical direction from the surface of the substrate 1 is the same as a total height of the micro lens 1a and the micro lens base 1b. The positioning member 1c has a width 27 in the horizontal direction is about 500 μm so that the laser diode board 2 adheres to the first reference surface 23a for mounting the laser diode board 2 on the substrate 1. The distance 28a on the laser beam axis between the first reference surface 23a of the positioning member 1c and the entrance surface 21 of the first micro lens 1a is set to a predetermined distance so that the first micro lens 1a is disposed to be capable of collimating the laser beam outputted from the emission surface 2a of the laser diode board 2. The thickness of the laser diode board 2 and the thickness of the sub-mounting member 7 are determined to conform the optical axis of the first micro lens 1a to the optical axis of the emission surface 2a of the laser diode board 2.

The second reference surface 23b contacts the micro lens board 4, and the first reference surface 23a contacts the laser diode board 2. The distance 28b between the first and second reference surfaces 23a, 23b is determined to set the distance between the micro lens board 4 and the laser diode board 2 to be a predetermined distance and to set the distance between the micro lens board 4 and the first micro lens 1a to be a predetermined distance.

The sub-mounting member 7 is made of material having thermal expansion coefficient, which is the same as the laser diode board 2. This is because the residual stress in the laser diode board 2 is required to reduce. However, the sub-mounting member 7 can be made of material having thermal expansion coefficient, which is different from the laser diode board 2. The sub-mounting member 7 and the semiconductor substrate 1 are connected with the first connection member 8. The sub-mounting member 7 and the laser diode board 2 are connected with the second connection member 9. Thus, in the semiconductor optical device 100, the laser beam outputted from the laser diode disposed on the laser diode board 2 is collimated by the first micro lens 1a and the micro lens board 4.

The sub-mounting member 7 is disposed between the laser diode board 2 and the substrate 1. However, when the thickness of the laser diode board 2 has no limitation in a case where the laser diode board 2 is manufactured, or when the optical axis of the first micro lens 1a coincides with the optical axis of the emission surface 2a of the laser diode board 2 by using the thickness of the laser diode board 2 with no sub-mounting member 7, no sub-mounting member 7 is necessitated in the device 100.

The heat sink 6 is bonded to the laser diode board 2 with the third connection member 10. The heat sink 6 is made of material having large thermal conductivity coefficient such as Cu, CuW, CuMo, Mo, and WC. Thus, the heat sink 6 radiates heat generated in the laser diode board 2 when the laser diode of the laser diode board 2 irradiates the laser beam. As shown in FIG. 3, an electrode pad 11 as an electric potential retrieving pad for driving the laser diode is formed on the heat sink 7. The electrode pad 11 and the laser diode board 2 are electrically connected with a wire 12.

The optical wave guide 3 is formed on the semiconductor substrate 1, and arranged to correspond one-on-one with the first micro lens 1a. Thus, the first micro lens 1a and the optical wave guide 3 are optically connected. The optical wave guide 3 is formed on an optical wave guide base 1d, which is integrally formed with the substrate 1. The optical wave guide 3 is composed of the first silicon oxide film 13, the second silicon oxide film 14 and the third silicon oxide film 15, which are laminated in this order. The second silicon oxide film 14 includes impurities with high concentration. The optical wave guide 3 is connected to the heat sink 6 with the fourth connection member 17.

Although the device 100 includes only one first micro lens 1a, the device 100 can include multiple first micro lenses 1a. In this case, the number of the laser diode is the same as the first micro lenses 1a. Therefore, the laser beam power for measuring the distance can be increased.

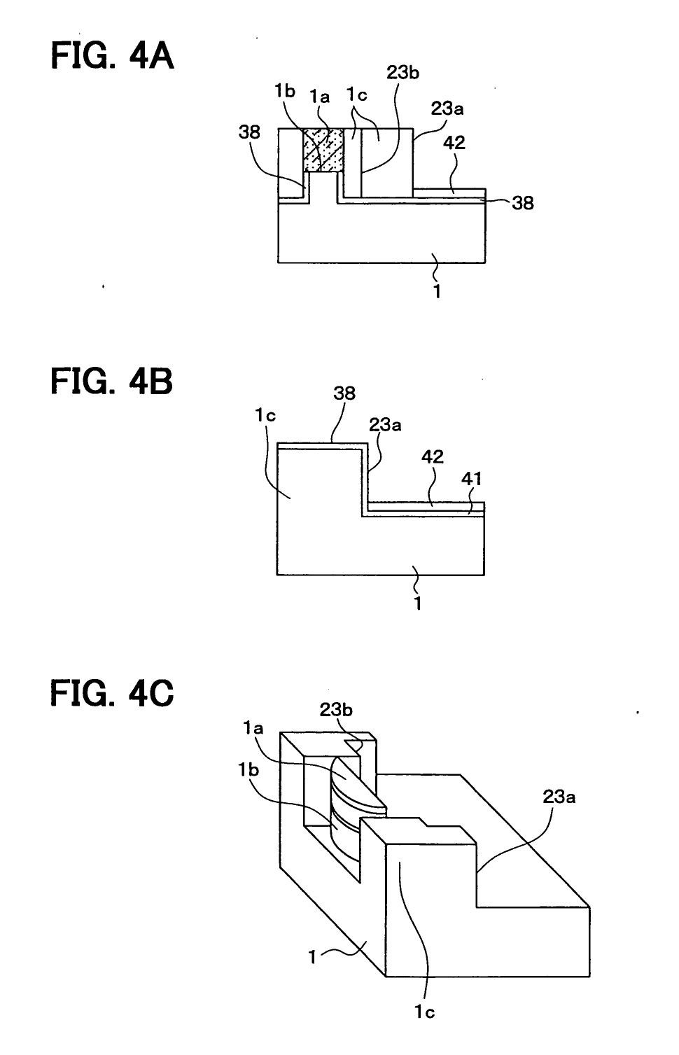

Next, the device 100 is manufactured as follows with reference to the drawings of FIGS. 4A-6C. The following device 100 includes two first micro lenses 1a. In FIGS. 4A-6C, only one first micro lens 1a is shown. The other first micro lens 1a is not shown.

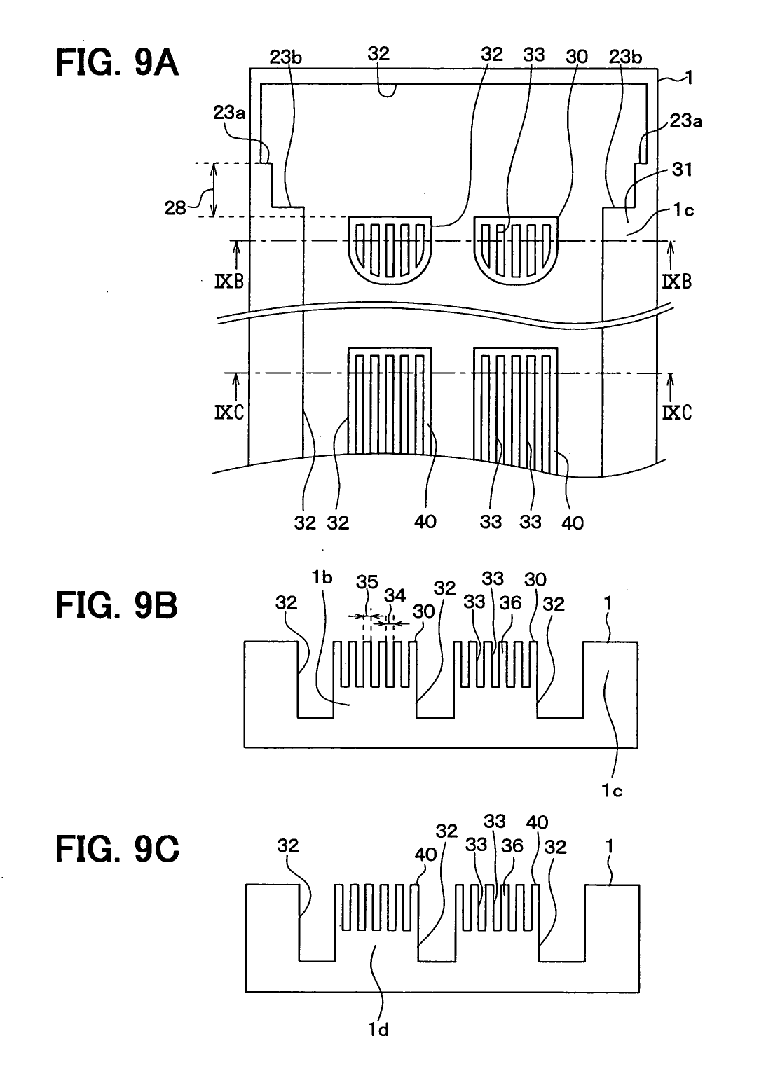

Firstly, the first micro lens 1a, the optical wave guide 3 and the positioning member 1c are formed on the semiconductor substrate 1. Specifically, they 1a, 3, 1c are formed in the following processes shown in FIGS. 9A-11.

In FIG. 9A, a silicon wafer is prepared for forming the substrate 1. An oxide film is formed on the surface of the substrate 1. Then, the oxide film is patterned so that the patterned oxide film works as a mask. As shown in FIGS. 9A and 9B, the surface of the substrate 1 is etched in such a manner that a first-micro-lens-to-be-formed region 30 and a positioning-member-to-be-formed region 31 are remained. Thus, the first trench 32 is formed. In this process, the first-micro-lens-to-be-formed region 30 of the substrate 1 is formed to be the same cross-sectional shape as the outline of the micro lens 1a. At the same time, the positioning member 1c is formed on the substrate 1. This process corresponds to the first process of the manufacturing method for manufacturing the device 100.

Further, the second trench 33 including multiple trenches is formed in the first-micro-lens-to-be-formed region 30 of the substrate 1. The trenches of the second trench 33 are disposed in parallel at a predetermined distance, and each trench of the second trench 33 has a predetermined width. Each trench of the second trench 33 has an opening, which is parallel to the optical axis. Specifically, the openings of the trenches are disposed in the same direction, which is parallel to the optical axis. The second trench 33 has a trench width 34 as a width of the opening of the trench and a wall width 35 as a width of a wall disposed between the trenches. The ratio of the trench width 34 and the wall width 35 is 0.55:0.45. For example, when the trench width 34 is 1.1 μm , the wall width 35 is set to be 0.9 μm . When the trench width 34 is 2.2 μm , the wall width 35 is set to be 1.8 μm . The mask of the patterned oxide film has a width of an opening and a distance between the openings of the mask, which correspond to the ratio of the trench width 34 and the wall width 35. Here, the bottom of the second trench 33, which remains without etching, provides the micro lens base 1b.

Thus, the first and second trenches 32, 33 are formed on the substrate 1 so that the micro lens base 1b and the positioning member 1c are formed. The outline of the micro lens base 1b corresponds to the outline of the first micro lens 1a. The height of the optical axis of the first micro lens 1a is defined by the height of the micro lens base 1b. Further, the height of the micro lens base 1b is determined by the depth of the second trench 33. Therefore, the height of the optical axis of the first micro lens 1a is determined by the depth of the second trench 33. Accordingly, when the second trench 33 is formed, the depth of the second trench 33 is adjusted in such a manner that the optical axis of the first micro lens 1a coincides with the optical axis of the laser diode board 2.

Further, the positioning member 1c is formed in such a manner that the first and second reference surfaces 23a, 23b of the positioning member 1c become parallel to the emission surface 2a of the laser diode board 2. The emission surface 2a of the laser diode board 2 is mounted on the substrate 1 in a latter process. In this embodiment, the positioning member 1c is formed in such a manner that the first reference surface 23a of the positioning member 1c becomes parallel to the entrance surface 21 of the first micro lens 1a. This is because the emission surface 2a of the laser diode board 2 faces in parallel to the entrance surface 21 of the first micro lens 1a so that the laser diode board 2 and the first micro lens 1a are optically connected.

Further, when the positioning member 1c is formed, the first reference surface 23a of the positioning member 1c and the entrance surface 21 of the first micro lens 1a are not disposed on the same plane, as shown in FIG. 3. Thus, the position of the first reference surface 23a of the positioning member 1c is determined to become uneven parallel to the entrance surface 21. Therefore, the first reference surface 23a of the positioning member 1c is disposed on the laser diode board side from the entrance surface 21 of the first micro lens 1a. Specifically, the relative position of the first reference surface 23a of the positioning member 1c relative to the position of the first micro lens 1a is determined in view of the focal length of the first micro lens 1a for collimating the laser beam outputted from the laser diode. For example, when the device 100 is used for collimating the laser beam, the distance 28 between an emission edge of the semiconductor laser and the first micro lens 1a is set to be 1000 μm in a case where a beam divergence angle of the laser beam is 90°. Specifically, when the entrance surface 21 of the first micro lens 1a approaches the emission edge of the semiconductor laser about 100 μm , the emission surface 2a, i.e., the side of the laser diode board 2 contacts the first reference surface 23a of the positioning member 1c. In this way, the positioning member 1c is formed.

The second reference surface 23b of the positioning member 1c for contacting the micro lens board 4 is disposed between the first reference surface 23a of the positioning member 1c for contacting the laser diode board 2 and the first micro lens 1a. As shown in FIGS. 9A and 9C, the first trench 32 is formed on the substrate 1 so that the first-micro-lens-to-be-formed region 30 is formed to be the same outline as the first micro lens 1a. Further, at the same time, the positioning member 1c is formed. An optical-wave-guide-to-be-formed region 40 is formed to be the same outline as the optical wave guide 3. In the optical-wave-guide-to-be-formed region 40, the second trench 33 is formed similar to the second trench 33 in the first-micro-lens-to-be-formed region 30. Thus, the optical wave guide base 1d is formed in the optical-wave-guide-to-be-formed region 40. The optical wave guide base 1d in the optical-wave-guide-to-be-formed region 40 has the same outline as the optical wave guide 3.

After etching the substrate 1, the surface of the sidewall of the first trench 32 is required to have certain flatness. Specifically, the sidewall of the first trench 32, which defines the outer circumference of the first-micro-lens-to-be-formed region 30, is required to have certain flatness. This is because the sidewall becomes the entrance surface 21 or the exit surface 22 of the laser beam. Therefore, after the substrate 1 is etched, the whole substrate 1 is annealed in hydrogen atmosphere so that the surface roughness of the sidewall of the trench becomes smaller. Then, the sidewall of the trench 32 is oxidized by a sacrificed-oxidation method so that the sidewall of the trench 32 becomes smooth. Therefore, the lens surface of the device 100, i.e., the entrance and exit surfaces 21, 22 are smoothed. This sacrificed-oxidation method is disclosed in Japanese Patent Application Publication No. 2002-231945. Further, the oxide film as the mask in the etching process is removed by dipping the substrate 1 in fluorinated acid.

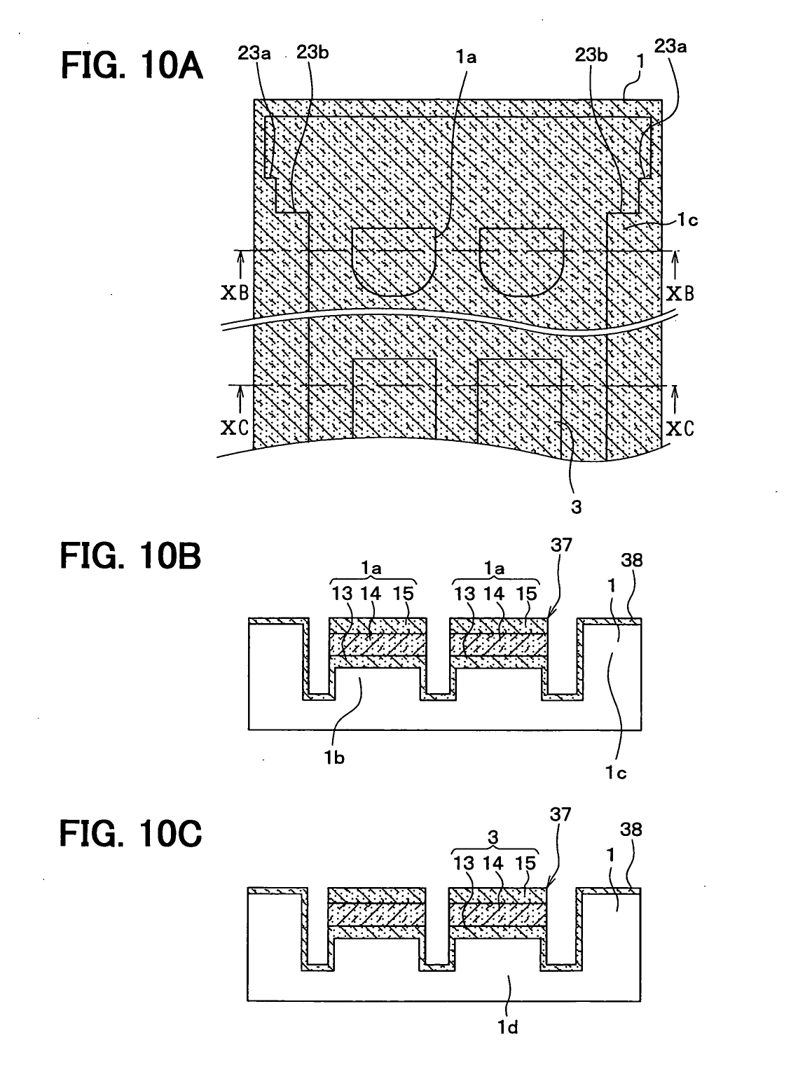

Next, as shown in FIG. 10A-10C, the first micro lens 1a is formed in the first-micro-lens-to-be-formed region 30, and the optical wave guide 3 is formed in the optical-wave-guide-to-be-formed region 40. Specifically, the substrate 1 is thermally oxidized so that the second trench 33 is filled with silicon oxide. Further, the sidewall 36 of the trench 33, which is disposed between the trenches of the second trench 33 and is made of silicon, is converted to silicon oxide. Thus, a silicon oxide layer 37 is formed in the second trench 33. In this way, the first micro lens 1a is integrally formed with the substrate 1. This process corresponds to the second process in the method for manufacturing the device 100.

Here, the thickness of the silicon oxide layer 37 is set to be equal to or larger than a sum of the trench width 34 and the wall width 35 of the second trench 33. In general, the thermal oxidation advances inside and outside of silicon material with the ratio of 0.45:0.55. The thermal oxidation speed to penetrate inside of the silicon material and the thermal oxidation speed to expand outside of the silicon material have the relationship expressed as 0.45:0.55. In this embodiment, the trench width 34 and the wall width of the second trench 33 corresponds to this ratio of 0.45:0.55. Therefore, the silicon oxide layer 37 fills in the second trench 33 by using the thermal oxidation process, and the sidewall 36 of the trench 33, which is a silicon layer, is converted into the silicon oxide layer 37 completely. Accordingly, when the whole second trench 33 is filled with the thermal oxidation film, i.e., the silicon oxide layer 37, the silicon layer as the sidewall 36 of the trench 33 disposed between the trenches is converted completely into the silicon oxide layer 37. Thus, at this time, the whole first-micro-lens-to-be-formed region 30 becomes the silicon oxide layer 37 as the first micro lens 1a. Thus, the first micro lens 1a is formed. At this time, an oxide film 38 is formed on the surface of the positioning member 1c and on the sidewall of the first trench 32. Therefore, the positioning member 1c is also formed together with the first micro lens 1a. After the thermal oxidation process, an anti-reflection film can be coated on the whole substrate 1 if it is required to improve optical transmission coefficient of the first micro lens 1a.

In the optical-wave-guide-to-be-formed region 40, the second trench 33 is filled with the silicon oxide layer 37 by the thermal oxidation method shown in FIGS. 10A-10C, similar to the first-micro-lens-to-be-formed region 30. Further, the silicon layer as the sidewall of the second trench 33 is completely converted to the silicon oxide layer 37. Thus, the silicon oxide layer 37 on the optical wave guide base 1d is formed together with the silicon oxide layer 37 on the micro lens base 1b.

Then, impurities is doped in the silicon oxide layer 37 on the optical wave guide base 1d and on the micro lens base 1b so that the first, second and third silicon oxide films 13-15 are formed. Thus, the first micro lens 1a and the optical wave guide 3 are formed. In this embodiment, the first micro lens 1a and the optical wave guide 3 are formed on the same substrate 1. However, the first micro lens 1a and the optical wave guide 3 can be formed on separate and different substrates, respectively. In this case, the different substrates are bonded together so that the first micro lens 1a and the optical wave guide 3 are connected optically.

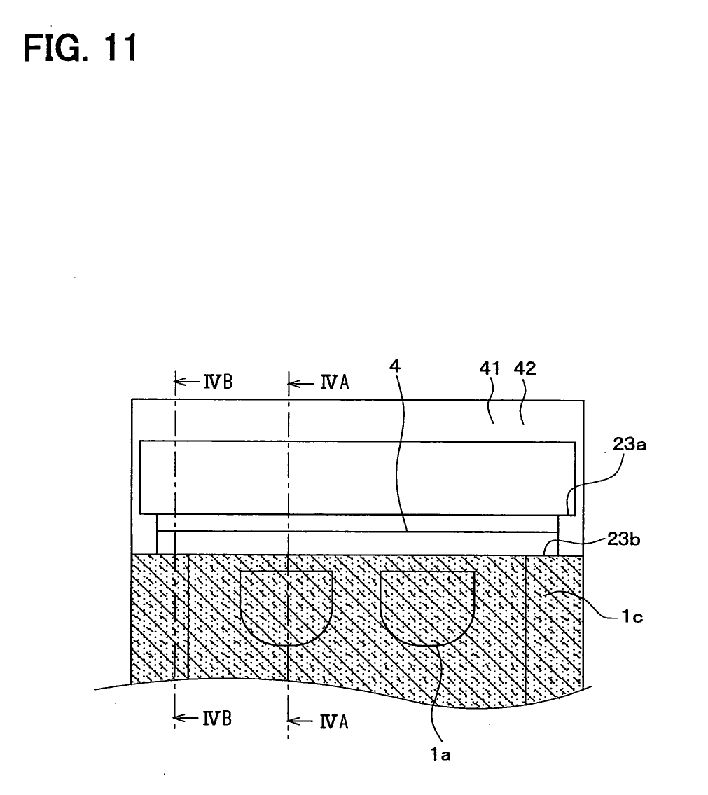

Next, as shown in FIG. 11, by using a metal mask, an Au/Ti film 42 is formed on the principal surface of the semiconductor substrate 1 as the wafer, on which the first micro lens 1a is disposed. Specifically, the Au/Ti film 42 is formed only on a laser-diode-board-to-be-mounted region 41 of the substrate 1. In FIG. 11, the optical wave guide 3 is not shown.

Titanium in the Au/Ti film 42 works for improving adhesion between an oxide film 38 on the substrate 1 and Au in the Au/Ti film 42. Gold in the Au/Ti film 42 works for bonding an eutectic alloy solder of Au—Sn series. The AuSn eutectic solder is preliminarily formed on the backside of the sub-mounting member 7. Thus, the Au/Ti film 42 is eutectically bonded to the AuSn eutectic solder. Further, the gold in the Au/Ti film 42 works for connecting to an Au wire in the latter process.

Then, the wafer as the substrate 1 is diced and cut into a chip. The dicing cut is performed at a cutting portion, which is not shown in FIG. 9A. Thus, the wafer is cut into the chip having predetermined dimensions. Before the wafer is cut, the wafer is coated with a protection film such as a photo resist to protect the surface of the first micro lens 1a from attaching silicon scraps generated by the dicing cut. Further, half of the wafer can be cut from the backside of the wafer, and then, the wafer is cleaved. Thus, the wafer can be cut into the chip without damaging the surface of the micro lens 1a. Thus, as shown in FIGS. 4A-4C, the first micro lens 1a and the positioning member 1c are formed on the substrate 1.

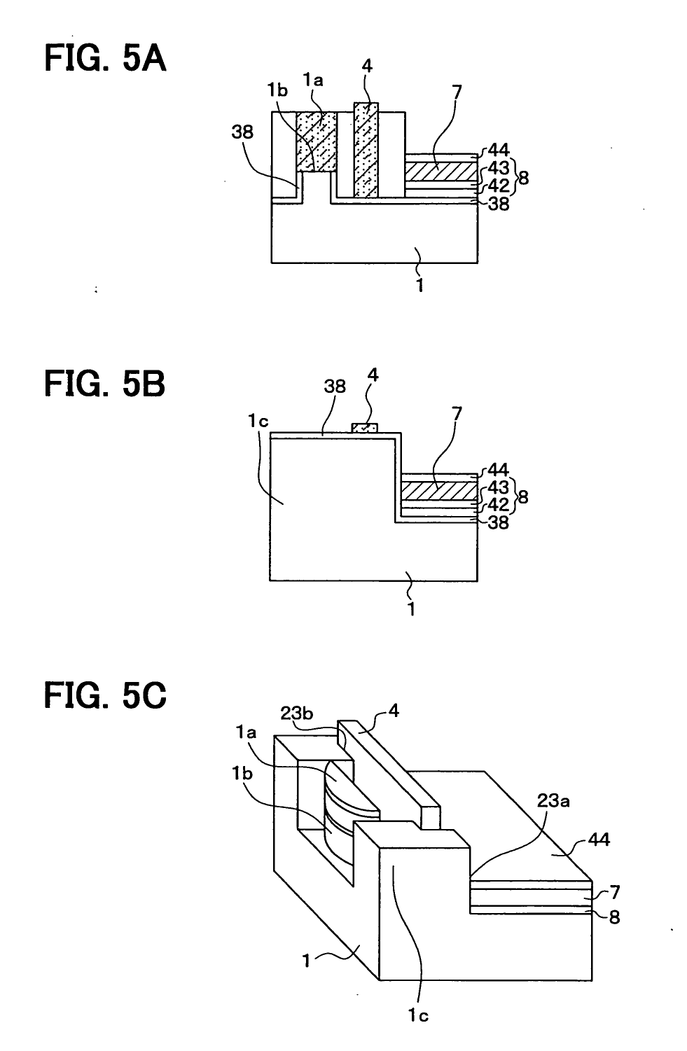

Next, as shown in FIGS. 5A-5C, the micro lens board 4 is adhered to the second reference surface 23b of the positioning member 1c so that the micro lens board 4 is mounted on the substrate 1. The sub-mounting member 7 is mounted on the substrate 1 in such a manner that the sub-mounting member 7 contacts the first reference surface 23a of the positioning member 1c. The sub-mounting member 7 works for conforming the optical axis of the laser diode to the optical axis of the first micro lens 1a. Here, connecting members 43, 44 are preliminarily formed on the foreside and backside of the sub-mounting member 7, respectively. The connecting members 43, 44 are made of eutectic alloy of Au—Sn series. The connecting member 43 disposed on the backside of the sub-mounting member 7 and the Au/Ti film 42 provide the first connection member 8.

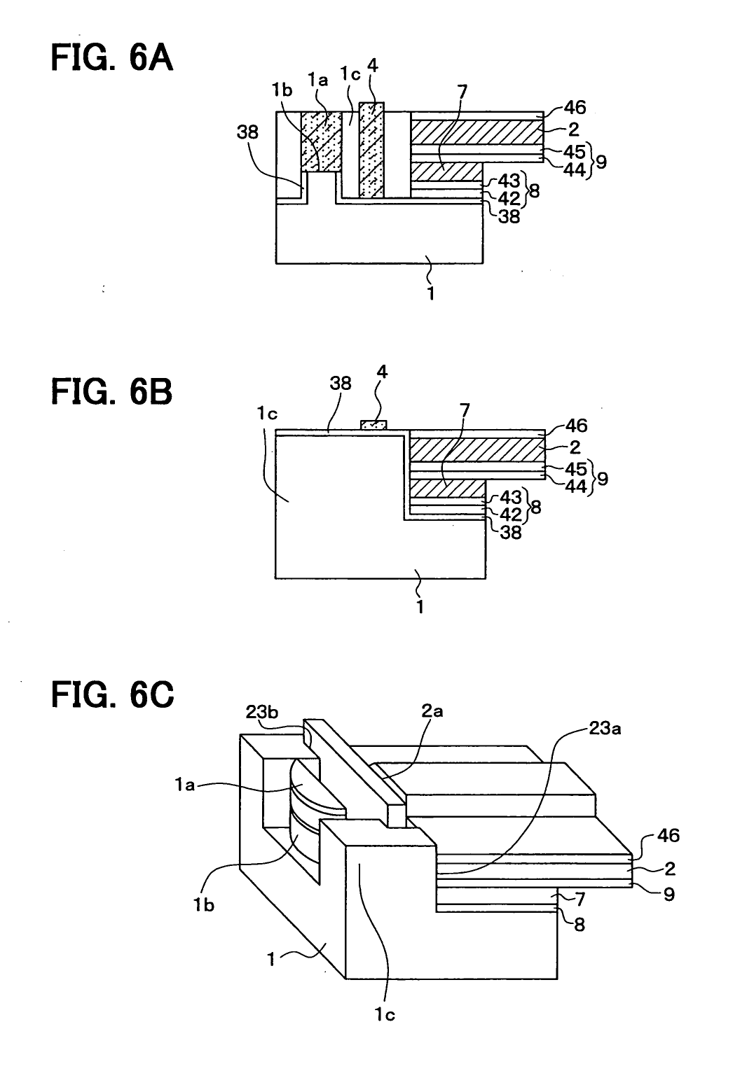

As shown in FIGS. 6A-6C, the side 2a of the laser diode board 2 contacts the first reference surface 23a of the positioning member 1c so that the laser diode board 2 is mounted on the sub-mounting member 7. Accordingly, the distance between the emission surface 2a of the laser diode and the first micro lens 1a can be secured appropriately. Thus, the emission surface 2a of the laser diode board 2 faces the entrance surface 21 of the first micro lens 1a so that the laser diode board 2 and the first micro lens 1a are optically connected. This process corresponds to the third process in the manufacturing method of the device 100. Au films 45, 46 are preliminarily formed on the foreside and the backside of the laser diode board 2. The Au film 45 disposed on the backside of the laser diode board 2 and the connecting member 44 disposed on the foreside of the sub-mounting member 7 provide the second connection member 9.

The position of the optical axis of the laser diode board 2 can be adjusted by using the thickness of the laser diode board 2. Accordingly, the thickness of the laser diode board 2 is set to be a predetermined thickness to conform the optical axis of the laser diode board 2 to the optical axis of the first micro lens 1a. Then, the laser diode board 2, the sub-mounting member 7 and the substrate 1 are bonded together in a press-heating process. In this process, they are heated to about 300° C., which is higher than an eutectic temperature of the Au—Sn eutectic alloy. Although the Au—Sn eutectic alloy is used for the connection member 8, 9, another material such as Au-Si eutectic alloy, Au—Ge alloy, and Sn—Pb alloy solder can be used for the connection member 8, 9.

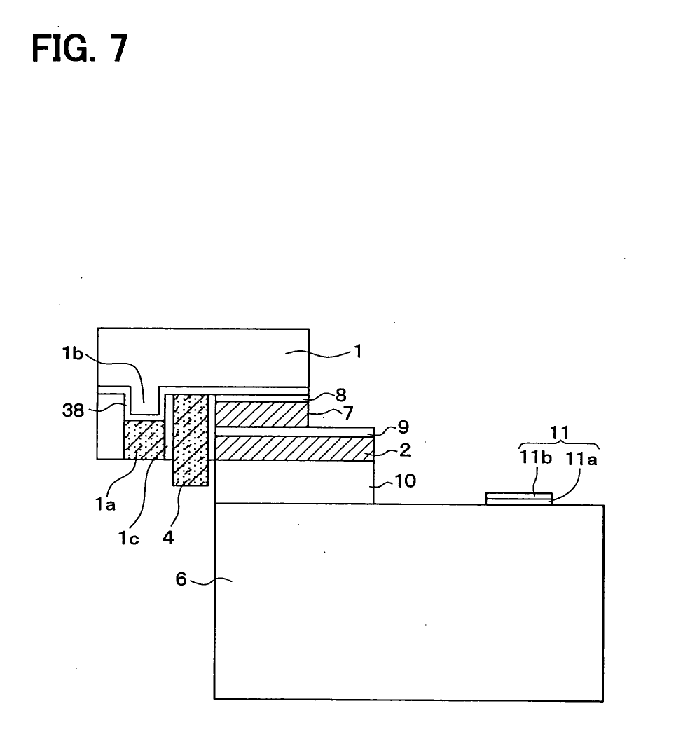

Next, as shown in FIG. 7, the substrate 1 is turned upside down. Then, the heat sink 6 is bonded to the substrate 1 with the third connecting member 10 such as In (i.e., indium) by a press annealing method. The heat sink 6 radiates the heat when the laser diode irradiates the laser beam. In this process, the indium is preliminarily deposited only on a connection region of the heat sink 6 by a mask deposition method. Further, an insulation film 11a such as polyimide film and an Au film 11b are preliminarily deposited on the surface of the heat sink 6 before the heat sink is bonded. The insulation film 11a and the Au film 11b provide the electrode pad 11. Although the third connection member 10 is made of In, the third connection member 10 can be made of Au—Si eutectic alloy, Au—Sn eutectic alloy, Au—Ge alloy or Sn—Pb alloy solder. Here, the micro lens board 4 is sandwiched between the heat sink 6 and the substrate 1 so that the micro lens board 4 is mounted on the substrate 1.

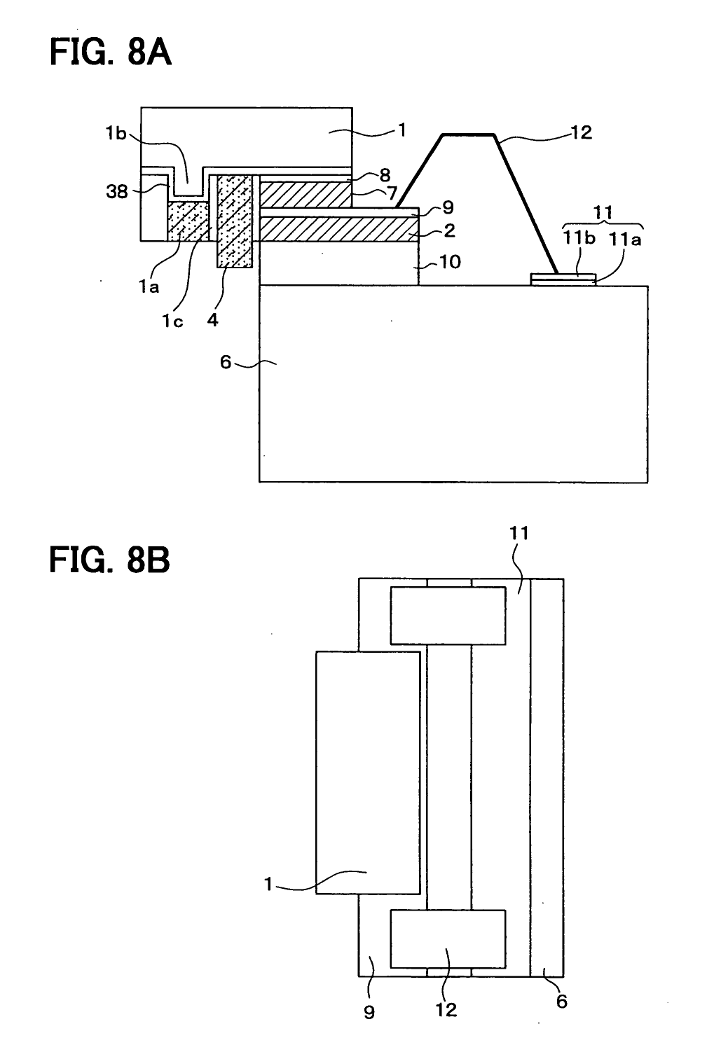

Then, as shown in FIGS. 8A and 8B, a bonding wire 12 is bonded to the substrate 1. Specifically, the laser diode board 2 and the electrode pad 11 disposed on the heat sink 6 are electrically connected with the wire 12. The wire 12 is, for example formed of an Au ribbon having a comparatively wide width. This is because the wide Au ribbon wire 12 can radiate heat generated in the laser diode. The position of the connection between the wire 12 and the electrode pad 11 can be provided different position different from the position shown in FIG. 8A. Further, the number of the wire 12 can be variable in accordance with characteristics of electronic device. Specifically, the wire 12 can be formed of multiple wires. Thus, the device 100 is completed.

In this embodiment, as shown in FIGS. 9A-9C, the substrate 1 is etched in one process so that the first micro lens 1a is formed from the first-micro-lens-to-be-formed region 30, and at the same time, the positioning member 1c is formed. Thus, the first micro lens 1a is formed from the first-micro-lens-to-be-formed region 30. Therefore, the positioning relationship between the first micro lens 1a and the positioning member 1c is determined only by the accuracy of etching. Therefore, the accuracy of the positioning relationship in this device 100 is higher than that in a case where the first micro lens 1a and the positioning member 1c are independently formed.

Further, the position of the first reference surface 23a of the positioning member 1c is determined to secure the appropriate distance between the entrance surface 21 of the first micro lens 1a and the emission surface 2a of the laser diode board 2. In FIGS. 6A-6C, a part of the side of the laser diode board 2, which is to be the emission surface 2a, contacts the first reference surface 23a of the positioning member 1c so that the laser diode board 2 is mounted on the substrate 1. Therefore, the distance between the emission surface 2a of the laser diode board 2 and the entrance surface 21 of the first micro lens 1a can become a predetermined distance. Accordingly, the accuracy of the positioning relationship between the first micro lens 1a and the laser diode board 2 is improved. Therefore, the optical coupling coefficient between the first micro lens 1a and the laser diode board 2 is also improved.

Furthermore, the micro lens board 4 contacts the second reference surface 23b of the positioning member 1c so that the micro lens board 4 is mounted on the substrate 1. Thus, the distance between the emission surface 2a of the laser diode board 2 and the micro lens board 4 as the second micro lens can become a predetermined distance. Further, the distance between the micro lens board 4 and the first micro lens 1a can become a predetermined distance.

Furthermore, as shown in FIG. 9A-9C, when the first-micro-lens-to-be-formed region 30 is formed, the optical-wave-guide-to-be-formed region 40 is also formed to be the optical wave guide 3. Thus, the optical wave guide 3 is formed from the optical-wave-guide-to-be-formed region 40. Therefore, the positioning relationship between the first micro lens 1a and the optical wave guide 3 is also determined by the etching accuracy. Here, the etching accuracy is defined as the positioning relationship itself when the first micro lens 1a and the optical wave guide 3 is formed by etching the substrate 1. The etching accuracy is comparatively high. Therefore, the accuracy of the positioning relationship between the first micro lens 1a and the optical wave guide 3 in this device 100 is higher than that in a case where the first micro lens 1a and the optical wave guide 3 are independently formed in the different substrates, respectively.

Specifically, the first micro lens 1a and the optical wave guide 3 are integrally formed on the substrate 1. Therefore, when the first micro lens 1a and the optical wave guide 3 are optically connected, no alignment for positioning the first micro lens 1a and the optical wave guide 3 is necessitated. Thus, the positioning accuracy of the first micro lens 1a and the optical wave guide 3 becomes higher.

Further, in the device 100, the micro lens base 1b and the positioning member 1c are disposed on the same substrate 1. Therefore, the positioning accuracy between the first micro lens 1a disposed on the micro lens base 1b and the positioning member 1c is determined by a manufacturing accuracy of the micro lens base 1b and the positioning member 1c. Accordingly, since the laser diode board 2 is mounted on the substrate 1 to contact the positioning member 1c, the positioning accuracy between the first micro lens 1a and the laser diode board 2 is also determined by the manufacturing accuracy of the micro lens base 1b and the positioning member 1c.

In the prior art, when a lens is manufactured by depositing an oxide film on a semiconductor substrate by a sputtering method, it is difficult to form the lens having a height higher than 5 μm . Further, even if the oxide film having the thickness of about 10 μm is formed by the sputtering method, since the oxide film is formed on whole surface of the substrate, the substrate may be bent by difference of the thermal expansion coefficient between silicon composing the substrate and oxide film. Therefore, when the wafer is fixed by using a wafer chuck in the etching process, the wafer may be damaged.

However, in the present embodiment, the first-micro-lens-to-be-formed region 30 of the substratel is formed to have the same outline as the first micro lens 1a. Further, the second trench 33 having multiple trenches is formed in the first-micro-lens-to-be-formed region 30. Then, the second trench 33 is filled with the silicon oxide layer 37, and the sidewall 36 of the second trench 33 is converted into the silicon oxide layer 37 so that the fist micro lens 1a is formed on the micro lens base 1b. Therefore, the first micro lens 1a having the height 24 higher than 5 μm can be easily formed. Further, since the oxide film having thick thickness is only formed in the first-micro-lens-to-be-formed region 30, the substrate 1 is prevented from bending even when the first micro lens 1a having the height 24 higher than 5 μm is formed.

In the prior art, a step between a mounting surface of a micro lens and a guide groove works for hooking a laser diode board. In this way, a relative relationship of positioning of the laser diode board and the micro lens is determined. Further, after the micro lens is formed on the substrate, the guide groove is formed on the substrate by a photo lithography method and an etching method. Therefore, when the substrate includes a convexity and concavity, the photo resist does not cover the substrate sufficiently. To cover the substrate with the photo resist sufficiently, the thickness of the photo resist is thickened. In this case, the photo resist is not sufficiently exposed in a photo lithography process. Thus, it is difficult to form the guide groove having a depth of about 100 μm. Therefore, it is required to reduce the step between the mounting surface of the micro lens and the guide groove. Thus, the laser diode board is not fixed and hooked at the step sufficiently.

However, in this embodiment, as shown in FIGS. 9A-9C, the first trench 32 is formed on the substrate 1 by the photo lithography method and the etching method before a convexity and concavity is formed on the substrate 1. At the same time, the positioning member 1c is formed. Therefore, the first trench 32 can be formed deeper than the guide groove in the prior art. Thus, the height 26 of the positioning member 1c on the substrate 1 can be higher than the step in the prior art. Accordingly, when the laser diode board 2 is mounted on the substrate 1 so that the first reference surface of the positioning member 1c contacts the laser diode board 2, the laser diode board 2 can be hooked and fixed to the positioning member 1c sufficiently.

In the prior art, all of the side of the laser diode board, which becomes an emission surface, contacts the step between the mounting surface of the micro lens and the guide groove. In this case, if a foreign particle penetrates between the side of the laser diode board and the step, the relative relationship of the positioning of the laser diode and the micro lens is deviated.

However, in this embodiment, as shown in FIGS. 3 and 6A-6C, a part of the side of the laser diode board 2, which becomes the emission surface 2a and corresponds to the positioning member 1c, contacts the first reference surface 23a of the positioning member 1c. Thus, the part of the emission surface 2a, which is a required minimum region for mounting the laser diode board 2, contacts the first reference surface 23a of the positioning member 1c. Therefore, even if a foreign particle penetrates between the laser diode board 2 and the positioning member 1c, the relative relationship of the positioning of the laser diode board 2 and the first micro lens 1a is prevented from deviating, compared with the prior art. Specifically, a contact area between the part of the emission surface 2a and the first reference surface 23a of the positioning member 1c becomes smaller, compared with the prior art. Therefore, the possibility for the foreign particle to penetrate between the laser diode board 2 and the positioning member 1c in the device 100 is reduced.

Although the device 100 includes the laser diode, the device 100 can include a light emitting diode.

In the prior art, a semiconductor optical device includes no micro lens base. Thus, a micro lens made of silicon oxide film is directly formed on a semiconductor substrate made of silicon. In this case, a certain angle is disposed between the side of the micro lens and the surface of the substrate at an interface between the substrate and the micro lens. Therefore, since a thermal expansion coefficient of the substrate is different from that of the micro lens, a stress is concentrated at the interface. Thus, the strength of the micro lens is reduced so that reliability of the micro lens is decreased.

However, in this embodiment, the shape of the micro lens base 1b made of silicon is the same as the first micro lens 1a made of silicon oxide. Specifically, the outline of the micro lens base 1b is the same as the first micro lens 1a. Thus, the side surface of the micro lens base 1b coincides with the side surface of the first micro lens 1a. Thus, no angle is formed at an interface between the first micro lens 1a and the micro lens base 1b. Although a certain angle is formed at another interface between the micro lens base 1b and the substrate 1, a stress generated at the interface between the first micro lens 1a and the micro lens base 1b is much reduced. The angle is formed at the other interface, which is apart from the interface between the first micro lens 1a and the micro lens base 1b. Therefore, the strength of the first micro lens 1a is improved so that reliability of the first micro lens 1a is increased.

Further, in the device 100, even when the temperature of the device 100 changes, the stress generated at the interface between the first micro lens 1a and the micro lens base 1b by the difference of the thermal expansion coefficient is reduced by a deformation of the micro lens base 1b. Thus, the strength of the first micro lens 1a is much improved so that reliability of the first micro lens 1a is increased.

Here, if the shape of the micro lens base 1b is larger than that of the first micro lens 1a, a certain angle is formed at the interface between the micro lens base 1b and the first micro lens 1a. Specifically, the angle is formed between the upper surface of the micro lens base 1b and the side surface of the first micro lens 1a. In this case, the stress may be concentrated at the interface. Therefore, it is necessitated for the micro lens base 1b to design the micro lens base 1b having the same shape as the first micro lens 1a.

Furthermore, since the shape of the micro lens base 1b is conformed to the shape of the first micro lens 1a, the distance between the fist micro lens 1a and the emission surface 2a of the laser diode board 2 can be designed to be an arbitrary distance. Therefore, when a focal length of the first micro lens 1a is short, the distance between the first micro lens 1a and the emission surface 2a of the laser diode board 2 can be easily shortened. Thus, the performance of the first micro lens 1a and the laser diode board 2 is improved.

Although the first optical part is the first micro lens 1a, the first optical part can be an optical device such as a prism or a mirror, or a polarization device such as a grating.

Although the second optical part is the laser diode, the second optical part can be a light emitting diode or an optical fiber.

### Second Embodiment

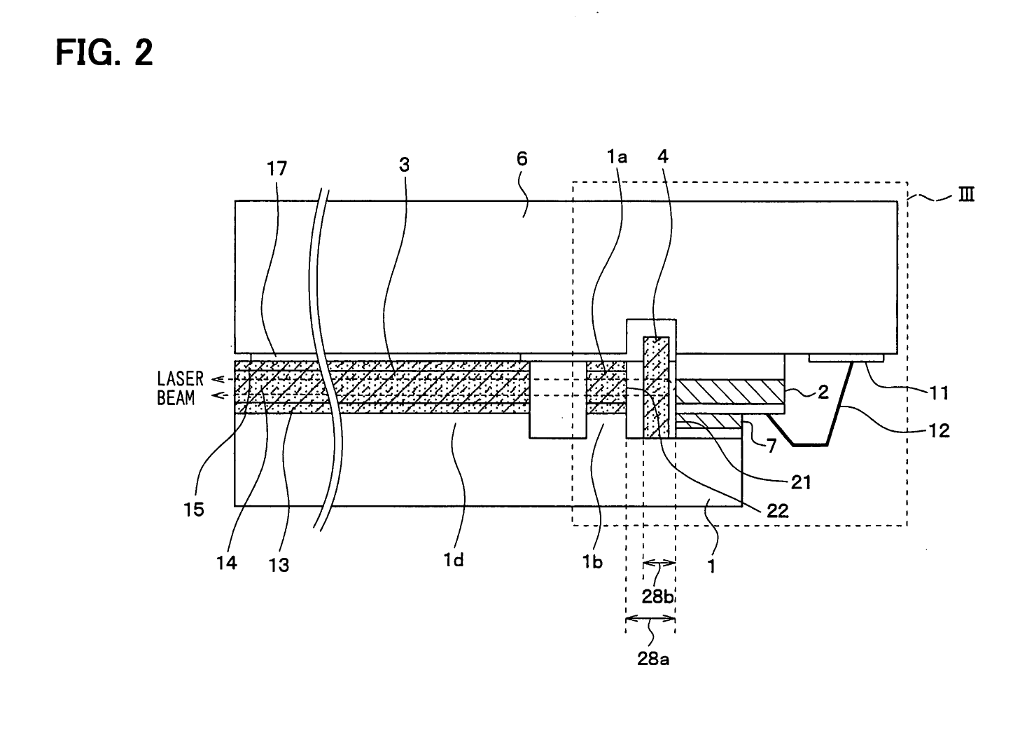

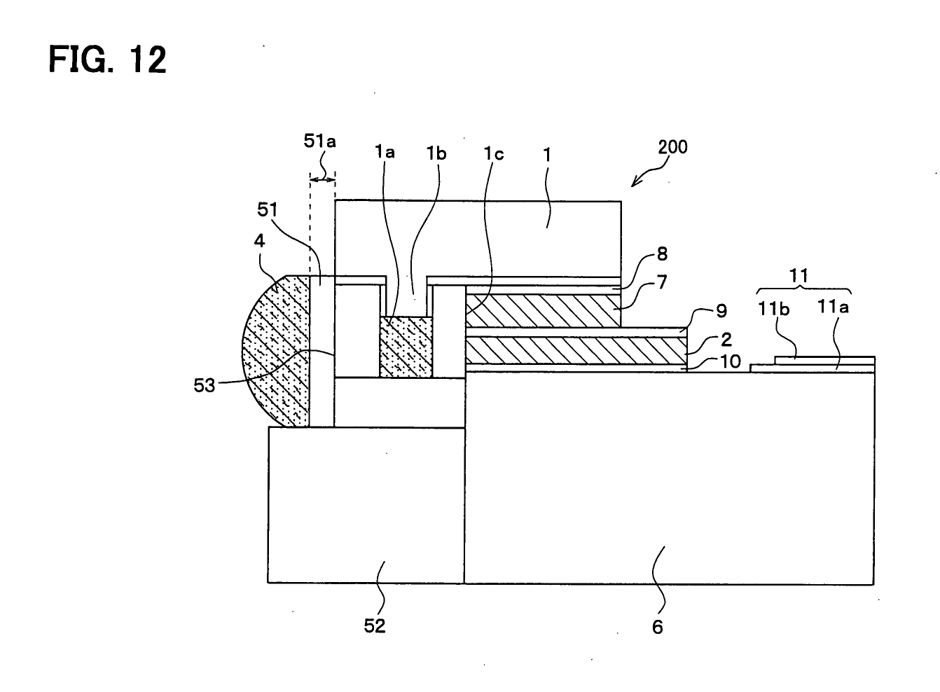

A semiconductor optical device 200 according to a second embodiment of the present invention is shown in FIG. 12. Here, the optical wave guide 3 is not shown in FIG. 12. Although the device 100 shown in FIG. 2 has a construction such that the micro lens board 4 is inserted between the first micro lens 1a and the laser diode board 2, the device 200 has another construction such that the first micro lens 1a is disposed between the micro lens board 4 and the laser diode board 2. This is, the first micro lens 1a is disposed on the laser diode board side from the micro lens board 4 in the optical axis direction. A lens mount board 52 having a partition 51 is connected to the heat sink 6. The micro lens board 4 is bonded to the partition 51.

The device 200 is manufactured as follows. The lens mount board 52 is bonded to the heat sink 6 with an eutectic solder. The micro lens board 4 is bonded to the partition 51 with adhesion such as a UV curable adhesion including epoxy resin as a major component. The distance between the micro lens board 4 and the emission surface 2a of the laser diode board 2 is adjusted with the thickness 51a of the partition 51 on the lens mount board 52, on which the micro lens board 4 is mounted. When high positioning accuracy is required, a surface 53 of the side of the positioning member 1c, which is opposite to the first reference surface 23a of the positioning member 1c, contacts the surface of the partition 51 so that the positioning of the micro lens board 4 is determined.

Although the lens mount board 52 is bonded to the heat sink 6 with the eutectic solder, the lens mount board 52 can be bonded to the heat sink 6 with other materials and other methods. For example, in a case where a connection temperature for connecting the lens mount board to the heat sink 6 is required to be lower as much as possible, or in a case where a sufficient connection strength is required, the lens mount board 52 is bonded to the heat sink 6 with a silver brazing method.

Thus, the device 200 has high accuracy of positioning of optical parts.

### Third Embodiment

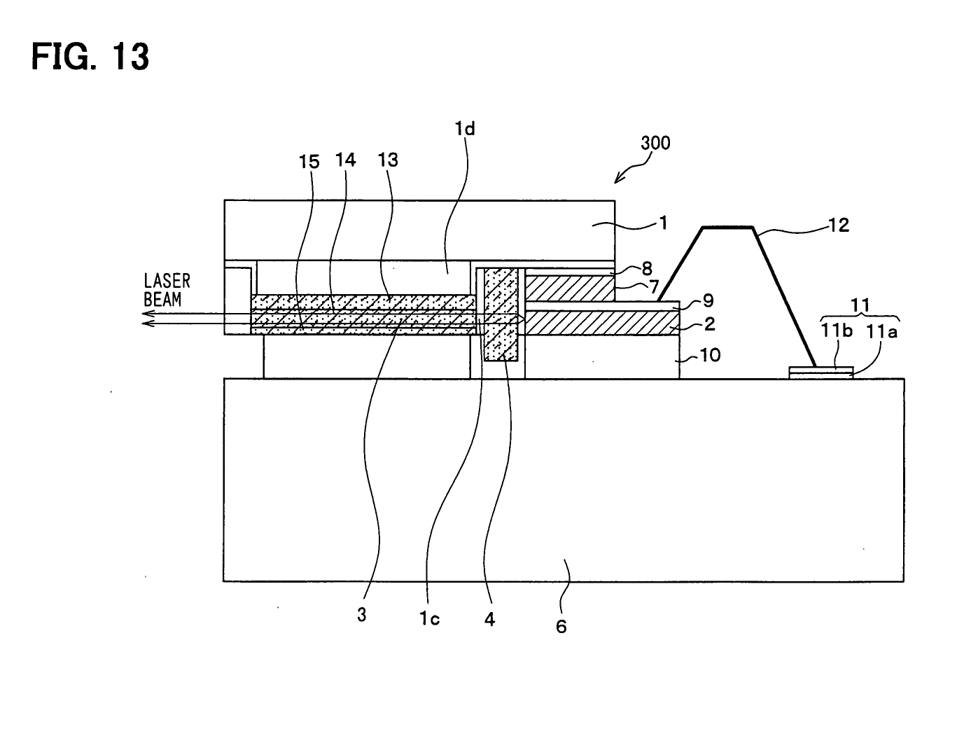

A semiconductor optical device 300 according to a third embodiment of the present invention is shown in FIG. 13. Although the device 100, 200 includes the first micro lens 1a as the first optical part, the device 300 includes the optical wave guide 3 as the first optical part. In the device 300, the micro lens board 4 as the second micro lens for collimating the laser beam expanding in the fast direction is disposed is disposed between the first optical part, i.e., the optical wave guide 3 and the laser diode board 2.

The device 300 includes the optical wave guide 3, the laser diode board 2 as the second optical part, and the heat sink 6. The optical wave guide 3 is integrally formed with the semiconductor substrate 1. The positioning member 1c is also integrally formed with the substrate 1. The side to be the emission surface 2a of the laser diode board 2 contacts the first reference surface 23a of the positioning member 1c so that the laser diode board 2 is mounted on the substrate 1.

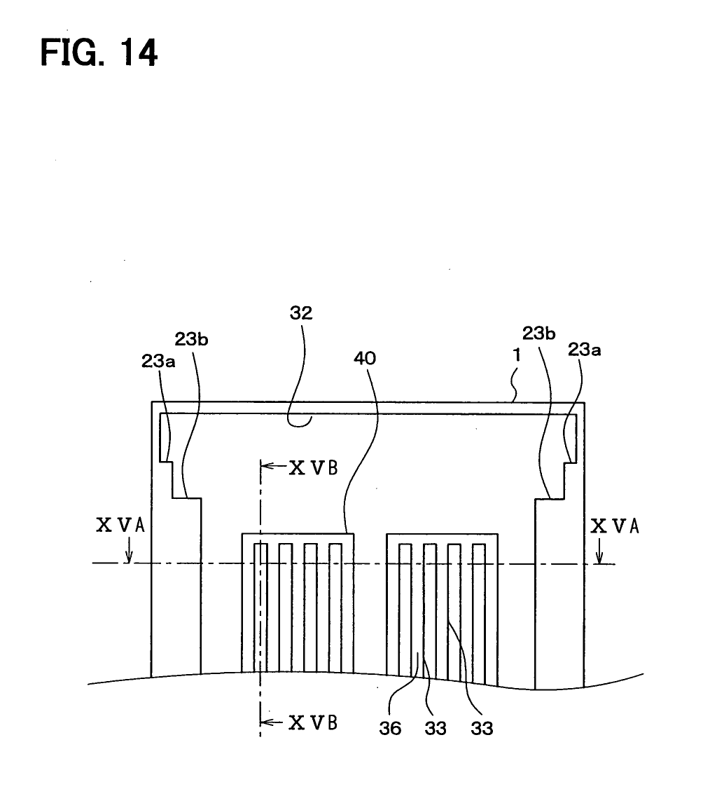

The device 300 is manufactured as follows. As shown in FIG. 14, the substrate 1 is prepared. Then, the surface of the substrate 1 is etched. In this case, the optical-wave-guide-to-be-formed region 40 instead of the first-micro-lens-to-be-formed region 30 is formed on the substrate 1. Specifically, the first trench 32 is formed on the substrate 1 so that the optical-wave-guide-to-be-formed region 40 is formed to be the outline of the optical wave guide 3. At the same time, the positioning member 1c is formed on the substrate 1. Further, the second trench 33 is formed in the optical-wave-guide-to-be-formed region 40.

Thus, the first and second trenches 32, 33 are formed in the substrate 1, so that the optical wave guide base 1d having the same outline as the optical wave guide 3 is formed, and the positioning member 1c is formed.

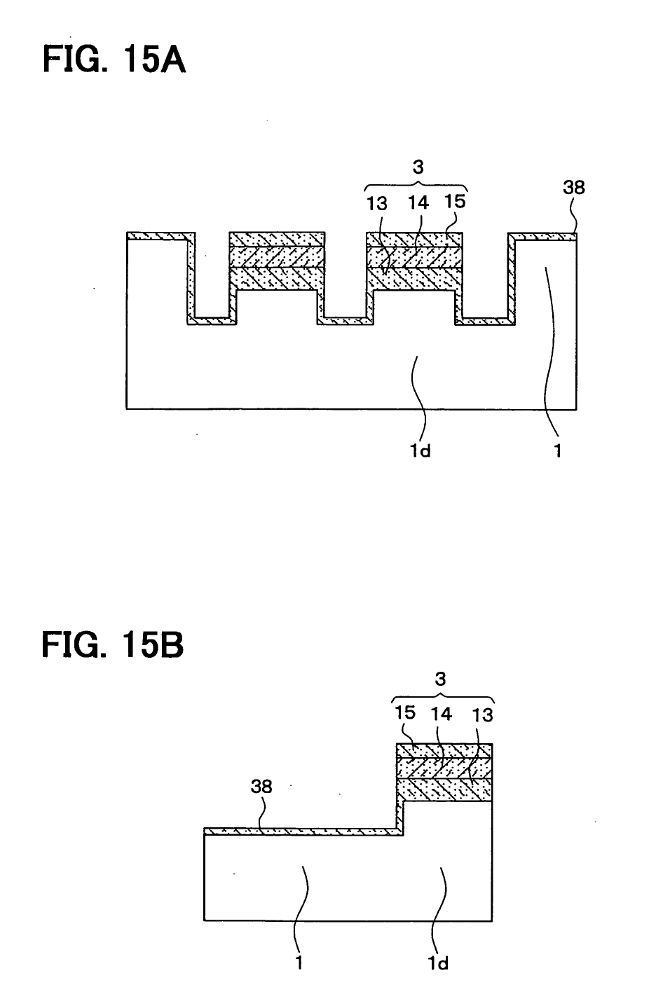

As shown in FIGS. 14 and 15A-15B, in the optical-wave-guide-to-be-formed region 40, the second trench 33 is filled with the silicon oxide by the thermal oxidation method. Further, the sidewall 36 of the trench 33 disposed between the trenches is converted into the silicon oxide. Thus, the silicon oxide layer 37 is formed on the optical wave guide base 1d. Then, the impurities is doped in the silicon oxide layer 37 so that the first, second third silicon oxide films 13-15 are formed. Thus, the optical wave guide 3 including the first, second third silicon oxide films 13-15 is formed.

Then, the micro lens board 4 contacts the positioning member 1c so that the micro lens board 4 is mounted on the substrate 1. Further, the sub-mounting member 7 and the laser diode board 2 are mounted on the substrate 1 so that the laser diode board 2 and the optical wave guide 3 are connected optically. Then, the micro lens board 4 is sandwiched between the substrate 1 and the heat sink 6 so that the laser diode board 2 and the optical wave guide 3 are bonded to the heat sink 6. Thus, the device 300 is completed.

In this embodiment, the substrate 1 is etched at one time so that the optical-wave-guide-to-be-formed region 40 is formed to be the shape of the optical wave guide 3, and at the same time, the positioning member 1c is formed in the substrate 1. Thus, the optical wave guide 3 is formed on the optical wave guide base 1d. Therefore, the relative relationship of the positioning between the optical wave guide 3 and the positioning member 1c is determined by the etching accuracy. Therefore, the accuracy of the positioning relationship between the optical wave guide 3 and the positioning member 1c in this device 300 is higher than that in a case where the optical wave guide 3 and the positioning member 1c are independently formed.

A part of the side of the laser diode board 2, which is to be the emission surface 2a, contacts the first reference surface 23a of the positioning member 1c so that the laser diode board 2 is mounted on the substrate 1. Therefore, the distance between the emission surface 2a of the laser diode board 2 and an entrance surface of the optical wave guide 3 can become a predetermined distance. Accordingly, the accuracy of the positioning relationship between the optical wave guide 3 and the laser diode board 2 is improved. Therefore, the optical coupling coefficient between the optical wave guide 3 and the laser diode board 2 is also improved.

Furthermore, the device 300 without the first micro lens 1a has optical parts, which is shorter than those of the device 100, 200. Specifically, the number of the optical parts of the device 300 is smaller than that of the device 100, 200. Therefore, the manufacturing cost of the device 300 can be reduced.

### Fourth Embodiment

The optical wave guide 3 in the device 1-3 is formed such that the optical-wave-guide-to-be-formed region 40 is formed to have the same outline of the optical wave guide 3, the optical-wave-guide-to-be-formed region 40 is converted into the oxide layer, and then, the impurities are doped in the oxide layer so that the optical wave guide 3 is formed. However, the optical wave guide 3 can be formed by other methods.

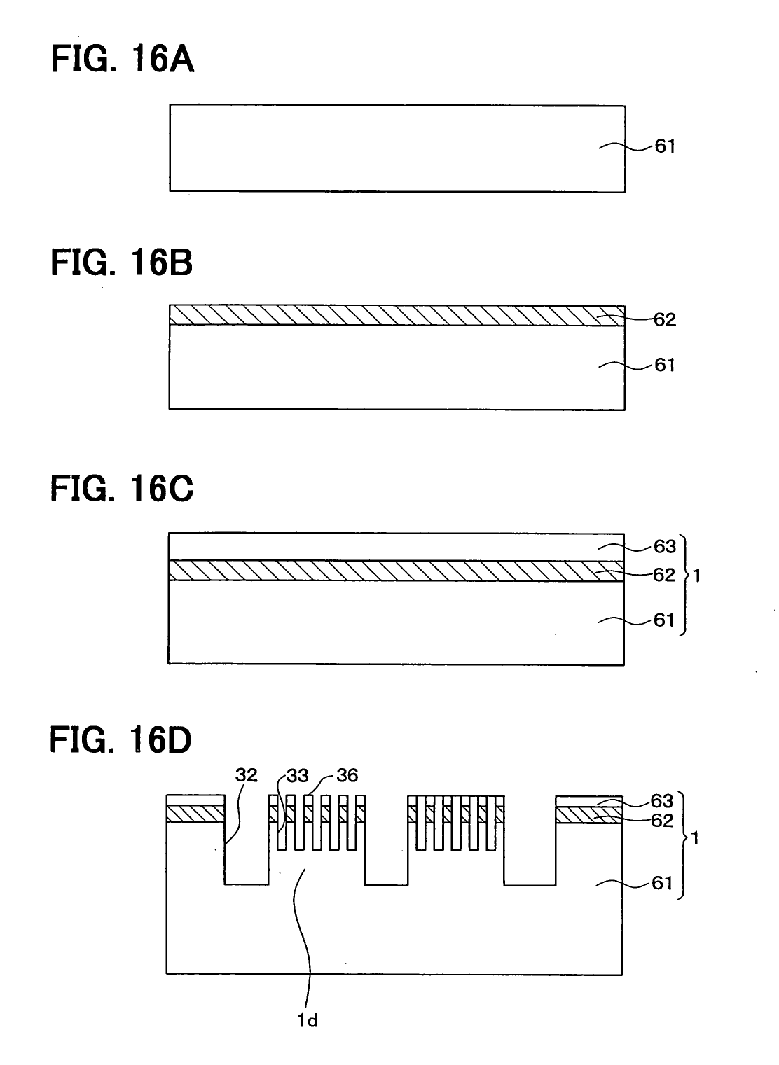

For example, the optical wave guide 3 according to a fourth embodiment of the present invention is formed as follows. As shown in FIG. 16, a silicon substrate 61 is prepared. Then, the first silicon layer 62 having high concentration impurities doped therein is deposited on the silicon substrate 61 by using an epitaxial growth method. Further, the second silicon layer 63 having no impurity is formed on the first silicon layer 62 by using the epitaxial growth method. Then, the first and second trenches 32, 33 are formed in the substrate 61. Further, the thermal oxidation is performed so that the optical wave guide 3 is formed.

Further, the first micro lens 1a can be formed by other methods. For example, the first-micro-lens-to-be-formed region 30 is formed to have the same outline of the first micro lens 1a without forming the second trench 33 therein. Then, a glass film is coated on the first-micro-lens-to-be-formed region 30 by using a SOG (i.e., a spin-on glass) method so that the first micro lens 1a is formed.

Although the laser diode board 2 and the heat sink 6 are bonded together with the third connection member 10 in the device 100-300 shown in FIGS. 1, 12, and 13, a semiconductor optical device can have other constructions.

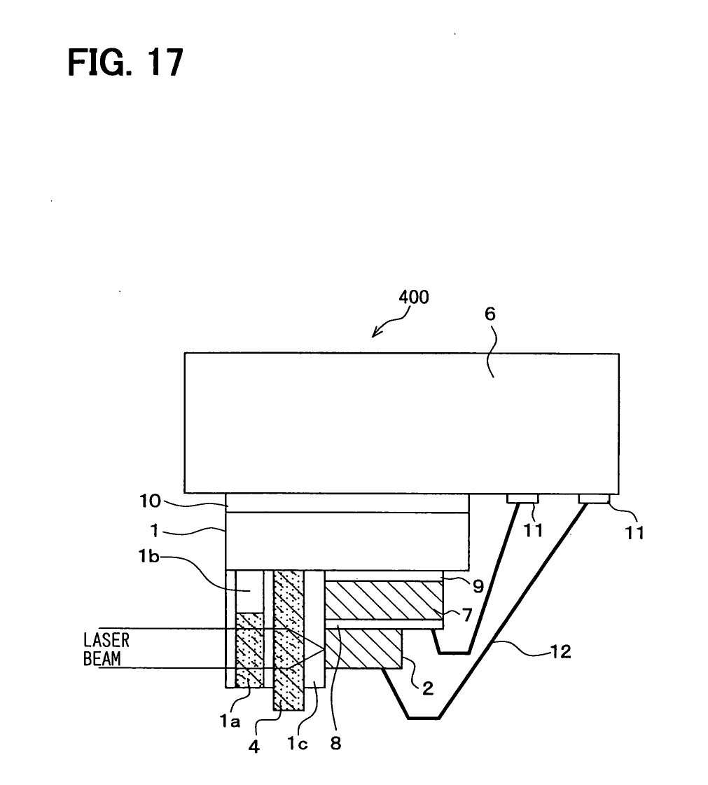

For example, in a case where characteristics of a semiconductor optical device 400 does not change even when a silicon plate is inserted between the laser diode board 2a and the heat sink 6, the device 400 can have the following construction shown in FIG. 17. Specifically, the device 400 can irradiate a low power laser beam. In the device 400, the first micro lens 1a is formed on the substrate 1, and then, the laser diode board 2 is mounted on the substrate 1. Then, the heat sink 6 is bonded to the substrate 1 with the third connection member 10.

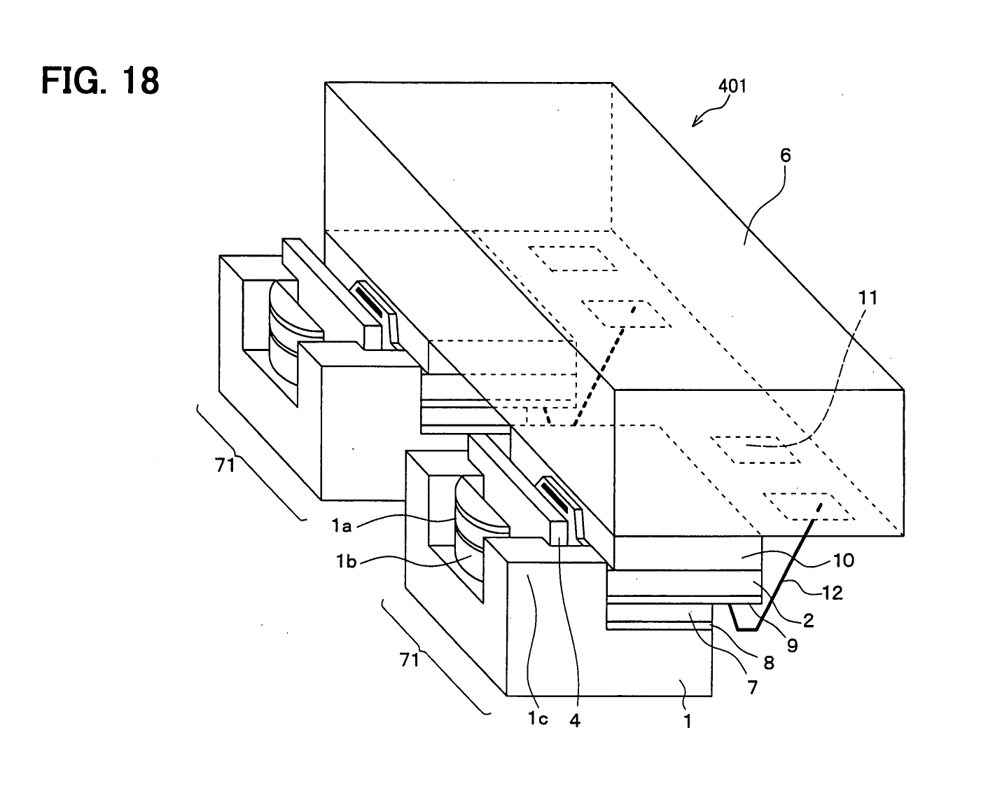

Further, another semiconductor optical device 401 has the following construction shown in FIG. 18. In the device 401, the substrate 1 and the laser diode board 2 bonded together provide an optical unit 71. In FIG. 18, the device 401 includes two optical units 71. In this case, the device 401 can irradiate a large power laser beam, since the device 401 includes two laser diode boards 2.

Here, to increase the laser power, it is considered that the number of the emission layers in the laser diode board 2 is increased. In this case, the length of the laser diode board 2 becomes longer, and therefore, the bending of the laser diode board 2 is easily occurred. Thus, the yielding ratio of the device is reduced.

However, in the device 401 having multiple laser diode boards 2, the length of the laser diode board is not necessitated to become longer. Therefore, the yielding ration of the device 401 is improved.

Such changes and modifications are to be understood as being within the scope of the present invention as defined by the appended claims.

1. A method for manufacturing a semiconductor optical device, which includes first and second optical parts disposed on a semiconductor substrate and optically connected each other, the method comprising the steps of:
etching the substrate so that a first-optical-part-to-be-formed region of the substrate is formed to have the same outline as the first optical part and a positioning member for determining a position of the second optical part is formed in the substrate;
forming the first optical part from the first-optical-part-to-be-formed region; and
mounting the second optical part on the substrate in such a manner that the second optical part contacts the positioning member.

2. The method according to claim 1,
wherein the positioning member contacts the second optical part at a contact surface,
wherein the first optical part has a first surface, which faces the second optical part,
wherein the positioning member is formed in such a manner that the contact surface of the positioning member is disposed on a second optical part side from the first surface of the first optical part, and
wherein the positioning member contacts the second optical part so that a distance between the first and second optical parts becomes a predetermined distance.

3. The method according to claim 2,
wherein the second optical part includes a second surface, which faces the first optical part, and
wherein the positioning member is disposed in such a manner that a part of the second surface of the second optical part contacts the positioning member when the second optical part is mounted on the substrate.

4. The method according to claim 1,
wherein, in the step of etching the substrate, a plurality of trenches are formed in the first-optical-part-to-be-formed region,
wherein, in the step of forming the first optical part, the trenches are filled with oxide material, which is provided by oxidizing a material of the substrate,
wherein, in the step of forming the first optical part, a sidewall portion of the trenches, which is disposed between the trenches, is converted to the oxide material, and
wherein the first optical part is provided by the converted side wall portion and the oxide material in the trenches.

5. The method according to claim 1,
wherein the first optical part is at least one of a micro lens and an optical wave guide.

6. The method according to claim 1,
wherein the second optical part is at least one of a laser diode, an light emitting diode, and an optical fiber.

7. The method according to claim 1,
wherein the first optical part is at least one of a micro lens and an optical wave guide,
wherein the second optical part is at least one of a laser diode, an light emitting diode, and an optical fiber,
wherein the first surface of the first optical part is an entrance surface for inputting a light, and
wherein the second surface of the second optical part is an emission surface for outputting the light.

8. The method according to claim 1,
wherein, in the step of etching the substrate, a third-optical-part-to-be-formed region is formed to have the same outline as a third optical part, and
wherein, in the step of forming the first optical part, the third optical part is formed from the third-optical-part-to-be-formed region.

9. The method according to claim 8,
wherein the third optical part is integrated with the substrate, and
wherein the first optical part is disposed between the second and third optical parts.

10. The method according to claim 8,
wherein, in the step of etching the substrate, a plurality of second type trenches are formed in the third-optical-part-to-be-formed region,
wherein, in the step of forming the first optical part, the second type trenches are filled with oxide material, which is provided by oxidizing a material of the substrate,
wherein, in the step of forming the first optical part, a sidewall portion of the second type trenches, which is disposed between the second type trenches, is converted to the oxide material, and
wherein the third optical part is provided by the converted side wall portion and the oxide material in the second type trenches.

11. The method according to claim 8,
wherein the first optical part is a micro lens, and
wherein the third optical part is an optical wave guide.

12. The method according to claim 4,
wherein each trench has a predetermined depth to conform an optical axis of the first optical part to an optical axis of the second optical part.

13. The method according to claim 1,
wherein the second optical part has a predetermined thickness for conforming an optical axis of the first optical part to an optical axis of the second optical part.

14. The method according to claim 1,
wherein the second optical part is mounted on the substrate through a sub-mounting member having a predetermined thickness for conforming an optical axis of the first optical part to an optical axis of the second optical part.

15. The method according to claim 1,
wherein, in the step of etching the substrate, a base is formed,
wherein the base is disposed under the first-optical-part-to-be-formed region, and
wherein the base has the same outline as the first optical part.

16. The method according to claim 15,
wherein the substrate and the base are made of silicon, and
wherein the first optical part is made of silicon oxide.

17. A semiconductor optical device comprising:
a semiconductor substrate;
a base integrated with the substrate;
a first optical part disposed on the base and integrated with the substrate;
a second optical part; and
a positioning member for determining a position of the second optical part,
wherein the positioning member is integrated with the substrate, and
wherein the second optical part contacts the positioning member so that the first and second optical parts are connected optically.

18. The device according to claim 17,
wherein the positioning member contacts the second optical part at a contact surface,
wherein the first optical part has a first surface, which faces the second optical part,
wherein the contact surface of the positioning member is disposed on a second optical part side from the first surface of the first optical part, and
wherein the positioning member contacts the second optical part so that a distance between the first and second optical parts becomes a predetermined distance.

19. The device according to claim 17,
wherein the base has the same outline as the first optical part.

20. The device according to claim 17,
wherein the second optical part includes a second surface, which faces the first optical part, and
wherein the second surface of the second optical part contacts the positioning member.

21. The device according to claim 17,
wherein the second optical part includes a second surface, which faces the first optical part, and
wherein the second surface of the second optical part includes a part, which contacts the positioning member.

22. The device according to claim 17, further comprising:
a third optical part integrated with the substrate,
wherein the first and third optical parts are connected optically.

23. The device according to claim 17,
wherein the first optical part is at least one of a micro lens and an optical wave guide.

24. The device according to claim 17,
wherein the second optical part is at least one of a laser diode, a light emitting diode and an optical fiber.

25. The device according to claim 17,
wherein the first optical part is at least one of a micro lens and an optical wave guide,
wherein the second optical part is at least one of a laser diode, an light emitting diode, and an optical fiber,
wherein the first surface of the first optical part is an entrance surface for inputting a light, and
wherein the second surface of the second optical part is an emission surface for outputting the light.

26. The device according to claim 22,
wherein the first optical part is a micro lens, and
wherein the third optical part is an optical wave guide.

27. The device according to claim 17,
wherein the substrate and the base are made of silicon, and
wherein the first optical part is made of silicon oxide.
